(19) United States
(12) Patent Application Publication
(10) Pub. No.: US 2026/0221714 A1
(43) Pub. Date: Jul. 30, 2026

(54) SEMICONDUCTOR LASER MODULE AND OPTICAL COMMUNICATION DEVICE

(71) Applicant: Mitsubishi Electric Corporation, Tokyo (JP)

(72) Inventors: Kosuke SHINOHARA, Tokyo (JP); Koichi AKIYAMA, Tokyo (JP)

(73) Assignee: Mitsubishi Electric Corporation, Tokyo (JP)

(21) Appl. No.: 19/157,394

(22) PCT Filed: Apr. 20, 2023
(86) PCT No.: PCT/JP2023/015719

§ 371 Date: Aug. 18, 2025

(51) Int. Cl. H01S 5/02251; H01S 5/10

(52) U.S. Cl. CPC H01S 5/02251; H01S 5/1007; H01S 5/1014

(57) ABSTRACT

This semiconductor laser module includes: a semiconductor laser element; a beam branching substrate formed by a dielectric and having an input waveguide with which a laser beam outputted from the semiconductor laser element is coupled, and a branching portion at which the input waveguide branches into a plurality of output waveguides, so that laser beams are respectively outputted from the plurality of output waveguides; and a plurality of optical fibers with which the plurality of laser beams outputted from the plurality of output waveguides are respectively coupled.

### TECHNICAL FIELD

The present disclosure relates to a semiconductor laser module and an optical communication device.

### BACKGROUND ART

For adapting to increase in communication speed, a method called Co-packaged optics is proposed (for example, Patent Document 1). In the Co-packaged optics, for suppressing deterioration in characteristics of a semiconductor laser due to temperature increase in an ASIC (Application Specific Integrated Circuit) in a central unit (Co-packaged chip), a semiconductor laser module is provided at a position away from the Co-packaged chip, and an output beam from the semiconductor laser module is coupled with a PIC (Photonic Integrated Circuit) in the Co-packaged chip through an optical fiber.

### CITATION LIST

### Patent Document

Patent Document 1: EP Patent Application Publication No. 3979524

Patent Document 2: Japanese Laid-Open Patent Publication No. 2002-244078

### SUMMARY OF THE INVENTION

### Problem to be Solved by the Invention

In the Co-packaged optics, the optical fiber is used for optical coupling between the semiconductor laser module and the PIC, and therefore a beam exceeding a damage threshold of the optical fiber cannot be used. Accordingly, in a case of using a semiconductor laser element having a beam output not smaller than the damage threshold of the optical fiber, it is necessary that a beam is branched in the semiconductor laser module so as to be reduced in beam intensity and then is coupled with the optical fiber. As a method for branching a beam, there is a method of using a spatial optical system as in Patent Document 2, for example. However, this method has a problem that the size of a semiconductor laser module increases due to the spatial optical system.

The present disclosure has been made to solve the above problem, and an object of the present disclosure is to provide a semiconductor laser module that has a reduced size and does not damage an optical fiber even when a laser beam outputted from a semiconductor laser element has a beam intensity greater than a damage threshold of the Optical Fiber.

### Means to Solve the Problem

A semiconductor laser module according to the present disclosure includes: a semiconductor laser element; a beam branching substrate formed by a dielectric and having an input waveguide with which a laser beam outputted from the semiconductor laser element is coupled, and a branching portion at which the input waveguide branches into a plurality of output waveguides, so that laser beams are respectively outputted from the plurality of output waveguides; and a plurality of optical fibers with which the plurality of laser beams outputted from the plurality of output waveguides are respectively coupled.

### Effect of the Invention

According to the present disclosure, it becomes possible to provide a semiconductor laser module that has a reduced size and does not damage an optical fiber even when a laser beam outputted from a semiconductor laser element has a beam intensity greater than a damage threshold of the optical fiber.

### BRIEF DESCRIPTION OF THE DRAWINGS

FIG. 1 is a schematic perspective view showing a structure of a semiconductor laser module according to embodiment 1.

FIG. 2A is a plan view showing a structure of a beam branching substrate of the semiconductor laser module according to embodiment 1.

FIG. 2B is a sectional view along line A-A in FIG. 2A and shows a structure of the beam branching substrate of the semiconductor laser module according to embodiment 1.

FIG. 2C is a sectional view along line B-B in FIG. 2A and shows a structure of the beam branching substrate of the semiconductor laser module according to embodiment 1.

FIG. 2D is a sectional view along line C-C in FIG. 2A and shows a structure of the beam branching substrate of the semiconductor laser module according to embodiment 1.

FIG. 3 is a plan view showing another structure of the beam branching substrate of the semiconductor laser module according to embodiment 1.

FIG. 4 is a plan view showing still another structure of the beam branching substrate of the semiconductor laser module according to embodiment 1.

FIG. 5 is a plan view showing still another structure of the beam branching substrate of the semiconductor laser module according to embodiment 1.

FIG. 6 is a plan view showing still another structure of the beam branching substrate of the semiconductor laser module according to embodiment 1.

FIG. 7 is an enlarged perspective view showing an example of a structure at a laser beam entrance part of the beam branching substrate of the semiconductor laser module according to embodiment 1.

FIG. 8 is an enlarged plan view showing another example of a structure of a laser beam entrance part of the beam branching substrate of the semiconductor laser module according to embodiment 1.

FIG. 9A is an enlarged plan view showing still another example of a structure of a laser beam entrance part of the beam branching substrate of the semiconductor laser module according to embodiment 1.

FIG. 9B schematically shows coupling of a laser beam in a sectional view along line A-A in FIG. 9A, of the beam branching substrate of the semiconductor laser module according to embodiment 1.

FIG. 9C is an enlarged sectional view schematically showing coupling of an output beam with an optical fiber, using a diffraction grating structure at a laser beam output part of the beam branching substrate of the semiconductor laser module according to embodiment 1.

FIG. 10A is a schematic perspective view showing still another structure of the semiconductor laser module according to embodiment 1.

FIG. 10B schematically shows coupling of a laser beam in a sectional view including an optical axis of a semiconductor laser element in FIG. 10A, of the semiconductor laser module according to embodiment 1.

FIG. 10C schematically shows coupling of a laser beam in an enlarged sectional view including an active layer of the semiconductor laser element of the semiconductor laser module having the structure shown in FIG. 10A and FIG. 10B, according to embodiment 1.

FIG. 11 is an enlarged perspective view showing an example of a structure at a coupling part with the optical fiber in the beam branching substrate of the semiconductor laser module according to embodiment 1.

FIG. 12 is a plan view showing another example of a structure at the output part of the beam branching substrate of the semiconductor laser module according to embodiment 1.

FIG. 13 is a schematic perspective view showing a structure of a semiconductor laser module according to embodiment 2.

FIG. 14 is a schematic perspective view showing a structure of a semiconductor laser module according to embodiment 3.

FIG. 15 is a schematic perspective view showing a structure of a semiconductor laser module according to embodiment 4.

FIG. 16 schematically shows a configuration of an optical communication device according to embodiment 5.

### DESCRIPTION OF EMBODIMENTS

### Embodiment 1

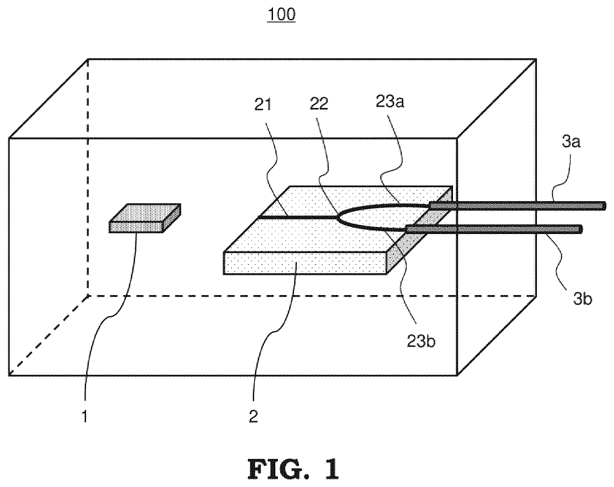

FIG. 1 is a schematic perspective view showing a configuration of a semiconductor laser module 100 according to embodiment 1. The semiconductor laser module 100 includes at least a semiconductor laser element 1, a beam branching substrate 2 formed by a plate-shaped dielectric, and two optical fibers 3a and 3b. The beam branching substrate 2 is provided between the semiconductor laser element 1 and the optical fibers 3a and 3b. In the semiconductor laser module 100, a laser beam outputted from the semiconductor laser element 1 is optically coupled with an input waveguide 21 of the beam branching substrate 2 and then is branched into two output waveguides 23a and 23b at a branching portion 22. The laser beams outputted from the output waveguides 23a and 23b are optically coupled with the optical fiber 3a and the optical fiber 3b, respectively. As described later, the number of the output waveguides and the number of the optical fibers are not limited to two, and may be two or more.

The semiconductor laser element 1 is a device that causes laser oscillation with current applied. That is, the semiconductor laser element 1 is an element that outputs a laser beam. As the semiconductor laser element 1, elements having various types of laser structures such as a distributed-feedback laser, an external cavity laser, a photonic crystal laser, and a photonic crystal surface-emitting laser, can be used. The beam branching substrate 2 is configured such that a damage threshold thereof for a laser beam is greater than a damage threshold of the optical fiber 3a and the optical fiber 3b. Therefore, even if the beam intensity of a laser beam outputted from the semiconductor laser element 1 is equal to or greater than the damage threshold of the optical fiber 3a or the optical fiber 3b, it is possible to perform beam coupling without damaging the optical fiber 3a and the optical fiber 3b, by branching the beam to intensities smaller than the damage threshold of the optical fiber in the beam branching substrate 2.

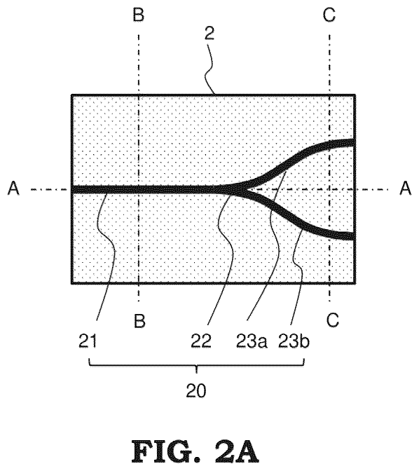

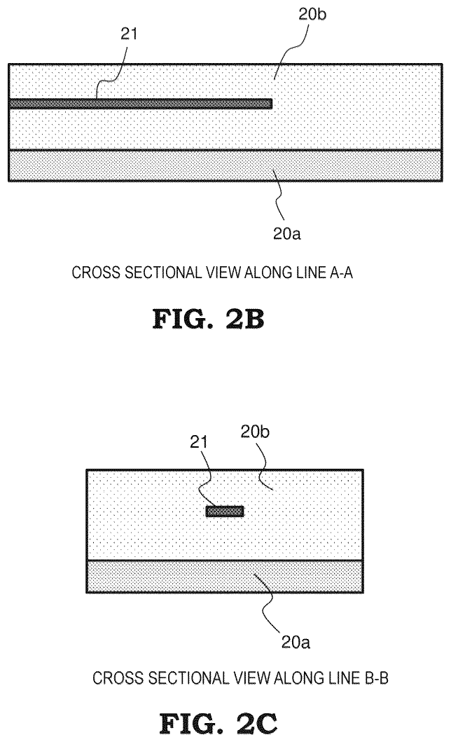

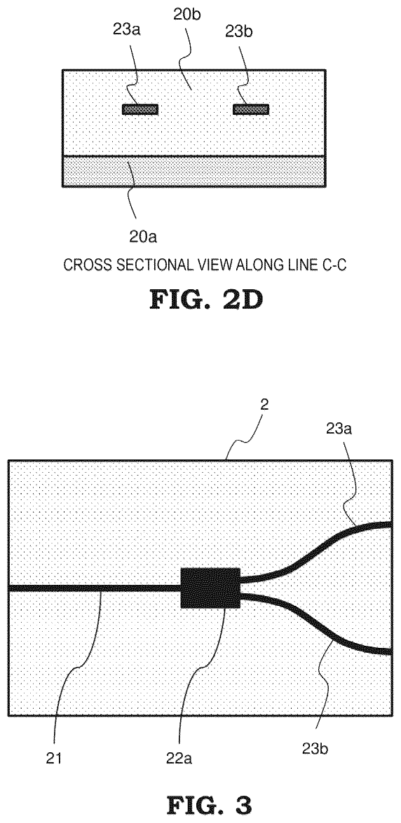

The beam branching substrate 2 is a member that receives a laser beam outputted from the semiconductor laser element 1, branches the laser beam into a plurality of waveguides, and optically couples the laser beams with a plurality of optical fibers. FIG. 2A to FIG. 2D show the detailed structure of the beam branching substrate 2. FIG. 2A is a plan view of the beam branching substrate 2, FIG. 2B is a sectional view along line A-A in FIG. 2A, FIG. 2C is a sectional view along line B-B in FIG. 2A, and FIG. 2D is a sectional view along line C-C in FIG. 2A. As shown in FIG. 2A, the beam branching substrate 2 has a waveguide composed of the input waveguide 21, the branching portion 22, and the two output waveguides 23a and 23b branching at the branching portion 22. As shown in the sectional views in FIG. 2B, FIG. 2C, and FIG. 2D, the beam branching substrate 2 has a Si-base structure such as SiN or SOI (Silicon On Insulator). The waveguide of the beam branching substrate 2 is formed inside a first dielectric layer 20b formed on a surface of a plate-shaped dielectric substrate 20a made of Si, SiN, or the like, and is made of a second dielectric material having a higher refractive index than the first dielectric layer 20b.

Around the waveguide (the input waveguide 21 in FIG. 2B and FIG. 2C, and the output waveguides 23a and 23b in FIG. 2D) of the beam branching substrate 2, for example, a SiO₂ layer (having a refractive index of about 1.45 at a wavelength of 1310 nm) is provided as the first dielectric layer 20b serving as a cladding layer. The waveguide is formed by the second dielectric material surrounded by the cladding layer and having a higher refractive index than the cladding layer. As the second dielectric material, Si (having a refractive index of about 3.50 at a wavelength of 1310 nm) or SiN (having a refractive index of about 1.99 at a wavelength of 1310 nm) is used. Owing to a refractive index difference between the second dielectric material forming the waveguide and the SiO₂ layer serving as the cladding layer, it is possible to use small-size waveguide dimensions, e.g., height 220 nm ×width 500 nm for a Si waveguide or width 400 nm×width 1000 nm for a SiN waveguide. Similarly, the branching portion such as a MMI coupler, a directional coupler, or a bending waveguide can also be reduced in size. Thus, using the beam branching substrate 2 for branching the laser beam outputted from the semiconductor laser element 1 makes it possible to reduce the size of the beam branching portion as compared to a case of using a spatial optical system as in conventional art. In the case of using the spatial optical system as in conventional art for branching the laser beam from the semiconductor laser element 1, it is difficult to perform mounting into a housing (e.g., QSFP-DD (length 36 mm) or OSFP (length 75.5 mm)) of a semiconductor laser module intended to be used for Co-packaged optics. However, using the beam branching substrate 2 for branching the laser beam from the semiconductor laser element 1 as described in the present disclosure makes it possible to perform mounting into the housing of the semiconductor laser module.

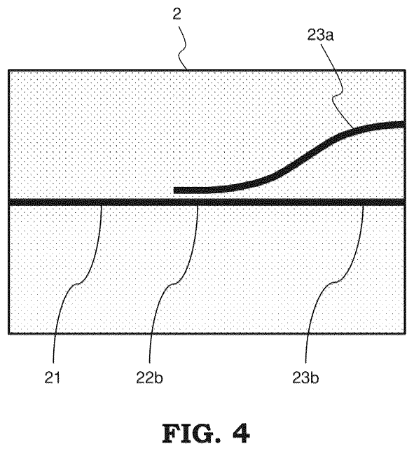

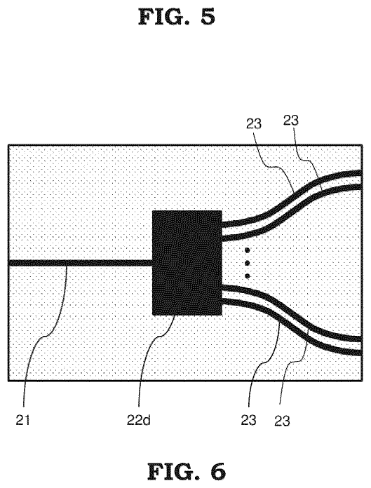

FIG. 2A shows the structure in which one input waveguide 21 branches into two output waveguides 23a and 23b at the branching portion 22 formed by a Y-branch waveguide. The structure of branching into a plurality of output waveguides, i.e., the branching portion, is not limited to the structure shown in FIG. 2A, and a 1×2 MMI (Multi-Mode Interference) coupler shown as a branching portion 22a in FIG. 3, a directional coupler shown as a branching portion 22b in FIG. 4, or the like can be used. In a case where the number of branches is three or more, i.e., the number of output waveguides is three or more, the branching portion can be formed to branch into three or more output waveguides 23 using a plurality of Y-branch waveguides as shown in a branching portion 22c in FIG. 5, or can be formed to branch into N output waveguides 23 using a 1×N MMI coupler as shown in a branching portion 22d in FIG. 6. As a matter of course, the Y-branch waveguide 22 in FIG. 2A, the 1×2 MMI coupler 22a in FIG. 3 or the 1×N MMI coupler 22d in FIG. 6, and the directional coupler 22b in FIG. 4 may be combined so as to branch into three or more output waveguides. It is desirable that the number of branches is selected to be such a minimum division number that the beam intensity becomes smaller than the damage threshold of the optical fibers. However, in a case of using a fiber connector composed of a plurality of optical fibers as with a MPO (Multi-fiber Push On) connector, the number of branches may be set in accordance with the number of the optical fibers.

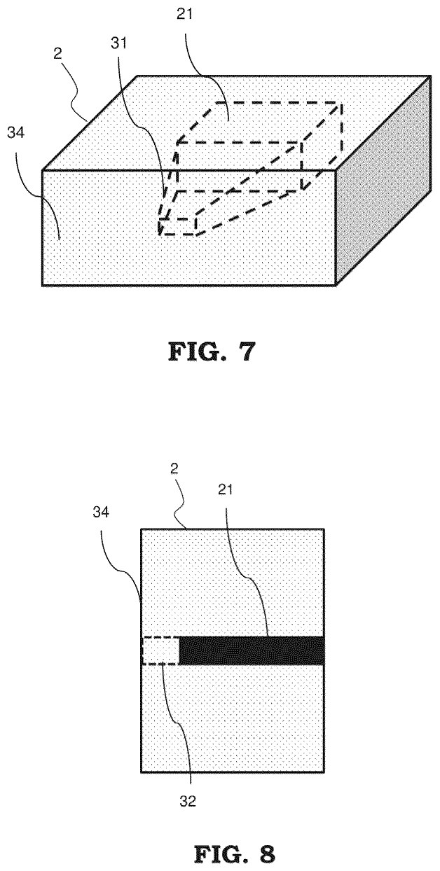

Further, receiving the laser beam from the semiconductor laser element 1 by the beam branching substrate 2 instead of an optical fiber has an advantage in the degree of freedom in designing of the waveguide. For example, in a case of a single mode fiber, the mode field diameter is a fixed value of 9.2 μm at a wavelength of 1310 nm, whereas the waveguide formed in the beam branching substrate 2 allows a mode field diameter to be adjusted through appropriate designing of the waveguide structure. The mode field diameter can be adjusted by providing a spot size converter 31 through which the width and the height of the waveguide change toward an entrance end surface 34 of the beam branching substrate 2 as shown in FIG. 7 or providing a window structure 32 in which there is no waveguide in the vicinity of the entrance end surface 34 as shown in FIG. 8, for example. By appropriately adjusting the mode field diameter through designing of the beam branching substrate 2, the beam density at the entrance end surface of the beam branching substrate 2 can be reduced as compared to a case of using an optical fiber, and it becomes possible to couple a beam having a greater intensity than the damage threshold of the optical fiber.

Similarly, also at an exit end surface, the mode field diameter can be adjusted by providing the spot size converter 31 shown in FIG. 7 or the window structure 32 shown in FIG. 8. By making the mode field diameter at the exit end surface close to the mode field diameter of the optical fiber, coupling efficiency between the output waveguide and the optical fiber can be improved.

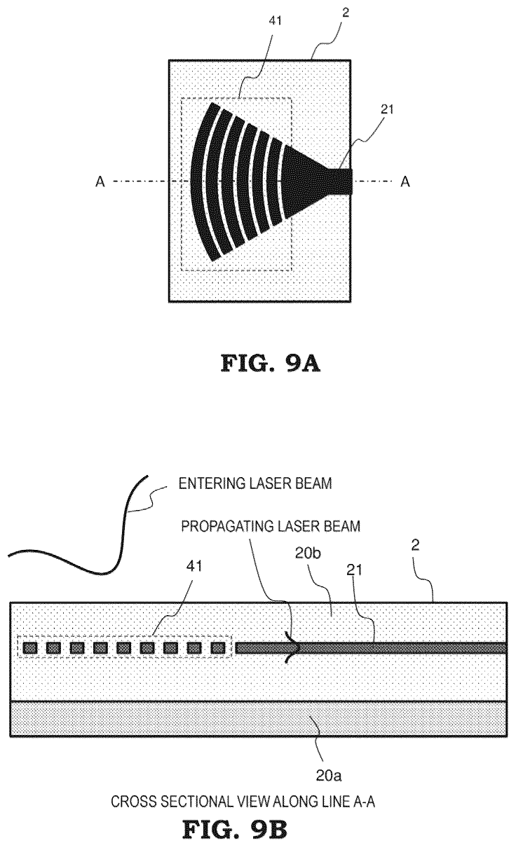

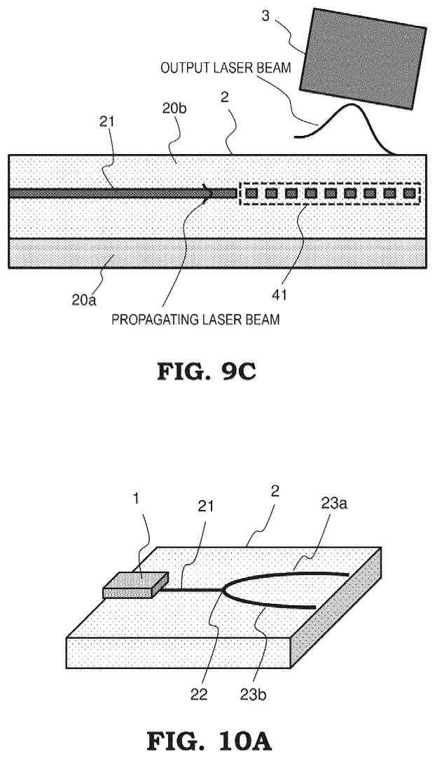

For optically coupling the semiconductor laser element 1 and the beam branching substrate 2 with each other, a diffraction grating structure 41 shown in FIG. 9A and FIG. 9B which is a sectional view along line A-A in FIG. 9A may be formed in the beam branching substrate 2. The entering laser beam from the semiconductor laser element 1 is coupled with the diffraction grating structure 41 and thus propagates to the input waveguide 21. In this case, the laser beam enters from an upper surface of the beam branching substrate 2, and therefore the laser module can be reduced in size as compared to a case where a laser beam enters from an end surface of the beam branching substrate 2. As shown in FIG. 9C, coupling of the laser beam through the diffraction grating structure 41 may be used also at a part where an output laser beam is coupled with the fiber 3, in the beam branching substrate 2.

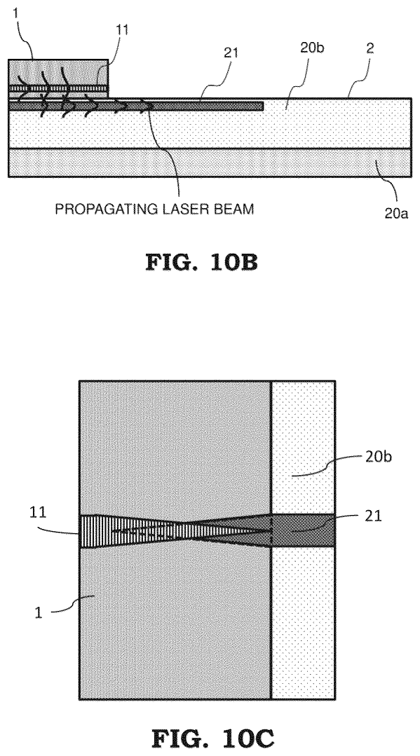

For optically coupling the semiconductor laser element 1 and the beam branching substrate 2 with each other, the semiconductor laser element 1 may be placed on the beam branching substrate 2, and a laser beam outputted from the semiconductor laser element 1 may be optically coupled with the input waveguide 21, using evanescent light penetrating from an active layer 11 of the semiconductor laser element 1. This structure is shown in FIG. 10A which is a perspective view, FIG. 10B which schematically shows a sectional view including the optical axis of the laser beam from the semiconductor laser element 1, and FIG. 10C which schematically shows a sectional view including the active layer 11 of the semiconductor laser element 1. With this structure, in a case where a beam enters from an end surface of the beam branching substrate 2, it becomes possible to improve coupling efficiency between the semiconductor laser element 1 and the beam branching substrate 2 and reduce the size of the semiconductor laser module, as compared to the structure in which coupling is performed through the diffraction grating structure 41 formed in the beam branching substrate 2.

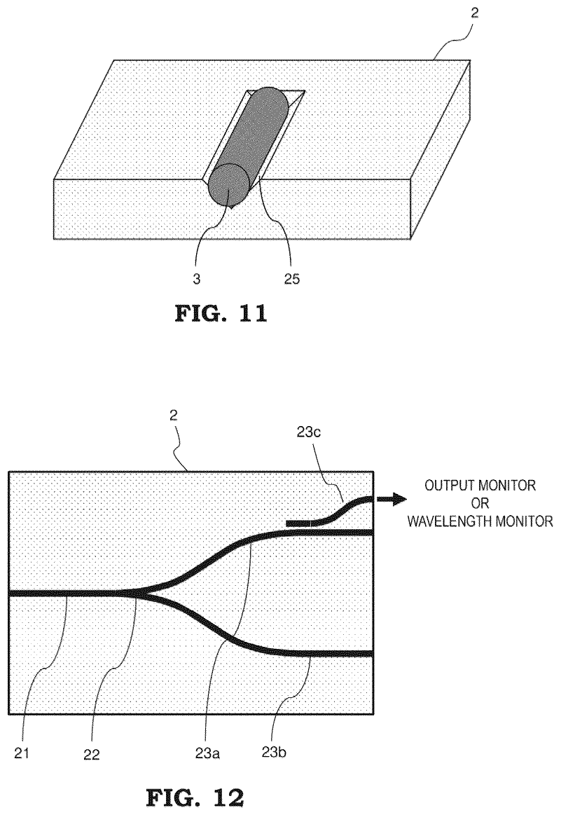

The optical fibers are components that receive laser beams outputted from the output waveguides of the beam branching substrate 2 and guide the laser beams to a PIC. The optical fibers are placed in accordance with the positions of the output waveguides of the beam branching substrate 2. For simplifying mounting of the optical fiber, a groove 25 shown in FIG. 11 may be provided at the exit end surface of the beam branching substrate 2. As shown in FIG. 11, the optical fiber 3 is placed at the groove 25, whereby mounting can be simplified.

It is not necessary to provide the same number of optical fibers as the number of the output waveguides of the beam branching substrate 2, and at least one of the output waveguides of the beam branching substrate 2 may be used as an output for an output monitor or an output for a wavelength monitor for the semiconductor laser element 1. In this case, for example, as shown in FIG. 12, using a directional coupler, a beam having a smaller intensity than in the output waveguide 23a coupled with the optical fiber may be taken out from the output waveguide 23a into an output waveguide 23c, so as to be used as an output for an output monitor or an output for a wavelength monitor.

### Embodiment 2

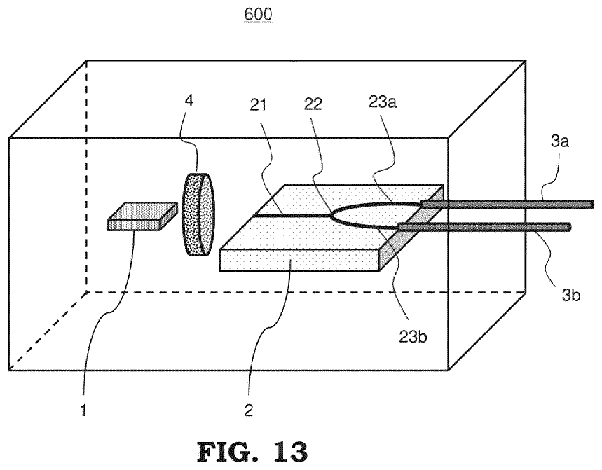

FIG. 13 schematically shows a semiconductor laser module 600 according to embodiment 2. The semiconductor laser module 600 includes at least the semiconductor laser element 1, the beam branching substrate 2, the optical fibers 3a and 3b, and a condenser lens 4. The condenser lens 4 is provided between the semiconductor laser element 1 and the beam branching substrate 2, and the beam branching substrate 2 having the input waveguide 21, the branching portion 22, and the output waveguides 23a and 23b branching at the branching portion 22 is provided between the condenser lens 4 and the optical fibers 3a and 3b. In the semiconductor laser module 600, a laser beam from the semiconductor laser element 1 is condensed by the condenser lens 4 and then is optically coupled with the input waveguide 21. The laser beam is branched into the two output waveguides 23a and 23b at the branching portion 22 and then laser beams outputted from the output waveguides 23a and 23b are optically coupled with the optical fibers 3a and 3b, respectively. As a matter of course, various types of beam branching substrates described in embodiment 1 can be used as the beam branching substrate 2, and also, the number of the output waveguides is not limited to two, and two or more output waveguides may be used.

The condenser lens 4 is a component that condenses a laser beam from the semiconductor laser element 1 and reduces the mode size. By reducing the mode size of the laser beam from the semiconductor laser element 1 and appropriately designing the waveguide structure of the beam branching substrate 2 in accordance with the mode size, it is possible to improve coupling efficiency between the semiconductor laser element 1 and the beam branching substrate 2.

### Embodiment 3

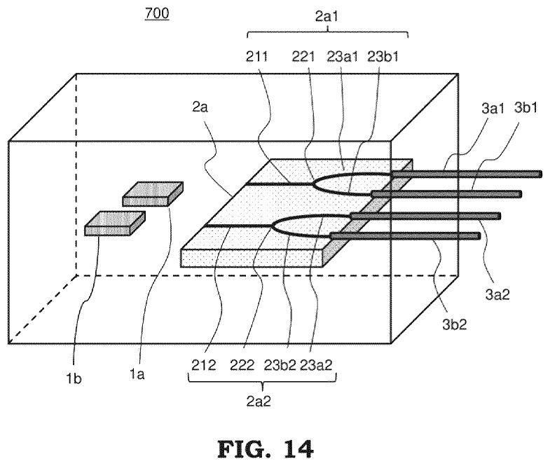

FIG. 14 schematically shows a semiconductor laser module 700 according to embodiment 3. The semiconductor laser module 700 includes two semiconductor laser elements 1a and 1b, a beam branching substrate 2a, and four optical fibers 3a1, 3b1, 3a2, 3b2. The beam branching substrate 2a has a first branching unit 2a1 composed of a branching portion 221 contiguous to an input waveguide 211 and output waveguides 23a1 and 23b1 branching at the branching portion 221, and a second branching unit 2a2 composed of a branching portion 222 contiguous to an input waveguide 212 and output waveguides 23a2 and 23b2 branching at the branching portion 222. A laser beam from the semiconductor laser element la is coupled with the input waveguide 211, a laser beam outputted from the output waveguide 23a1 is optically coupled with the optical fiber 3a1, and a laser beam outputted from the output waveguide 23b1 is optically coupled with the optical fiber 3b1. Similarly, a laser beam from the semiconductor laser element 1b is coupled with the input waveguide 212, a laser beam outputted from the output waveguide 23a2 is optically coupled with the optical fiber 3a2, and a laser beam outputted from the output waveguide 23b2 is optically coupled with the optical fiber 3b2. In FIG. 14, the example in which one input waveguide is branched into two output waveguides in each of the first branching unit 2a1 and the second branching unit 2a2 is shown. However, as a matter of course, the number of the output waveguides is not limited to two, and a structure of branching into three or more output waveguides may be used. In FIG. 14, the first branching unit 2a1 and the second branching unit 2a2 are provided in one beam branching substrate 2a. However, the first branching unit 2a1 and the second branching unit 2a2 may be respectively provided in separate beam branching substrates. In this case, the branching structure or the structure at the entrance end surface or the exit end surface need not be the same between the beam branching substrates.

In the semiconductor laser module 700 according to the present embodiment 3, since two or more semiconductor laser elements are provided, the sum of the intensities of beams outputted from the semiconductor laser module 700 can be increased.

### Embodiment 4

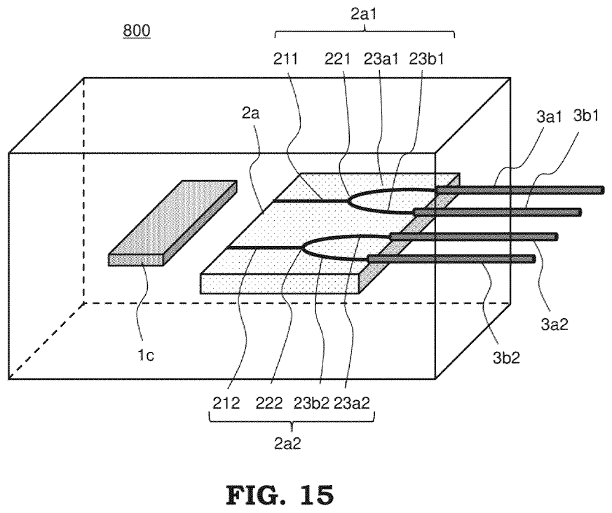

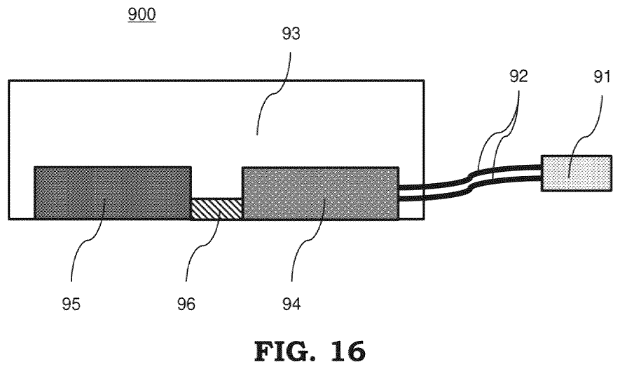

FIG. 15 schematically shows a semiconductor laser module 800 according to embodiment 4. The semiconductor laser module 800 includes a semiconductor laser element (semiconductor laser array element) 1c which outputs two laser beams, the beam branching substrate 2a, and four optical fibers 3a1, 3b1, 3a2, 3b2. The beam branching substrate 2a is provided between the semiconductor laser element 1c and the optical fibers. The beam branching substrate 2a in the semiconductor laser module 800 has a structure having the first branching unit 2a1 and the second branching unit 2a2, as in the beam branching substrate 2a described in embodiment 3. The laser beams outputted from the semiconductor laser element 1c are optically coupled with the respective input waveguides 211 and 212, and respective laser beams are branched into two output waveguides 23al and 23b1 and two output waveguides 23a2 and 23b2. Then, laser beams outputted from the respective output waveguides are optically coupled with the optical fibers 3a1, 3b1, 3a2, 3b2. In FIG. 15, the semiconductor laser element 1c that outputs two laser beams is shown. However, the number of outputted laser beams is not limited to two, and a semiconductor laser element (semiconductor laser array) that outputs a plurality of laser beams not less than three may be used, and the number of input waveguides of the beam branching substrates, i.e., the number of branching units, may be set in accordance with the number of outputted laser beams. In FIG. 15, the example in which one input waveguide is branched into two output waveguides in each of the first branching unit 2a1 and the second branching unit 2a2, is shown. However, as a matter of course, the number of the output waveguides is not limited to two, and a structure of branching into three or more output waveguides may be used. In FIG. 15, the first branching unit 2a1 and the second branching unit 2a2 are provided in one beam branching substrate 2a. However, the first branching unit 2a1 and the second branching unit 2a2 may be respectively provided in separate beam branching substrates. In this case, the branching structure or the structure at the entrance end surface or the exit end surface need not be the same between the beam branching substrates.

In the semiconductor laser module according to the present embodiment 4, since the semiconductor laser element 1c which outputs two or more laser beams is provided, the sum of the intensities of beams outputted from the semiconductor laser module can be increased.

### Embodiment 5

FIG. 16 schematically shows a configuration of an optical communication device 900 according to embodiment 5. The optical communication device 900 includes any of the semiconductor laser modules described in embodiments 1 to 4, as a semiconductor laser module 91 in FIG. 16. In FIG. 16, only a PIC 94, an ASIC 95, and an electronic circuit 96 connecting the PIC 94 and the ASIC 95 in a Co-packaged chip 93, are shown in addition to the semiconductor laser module 91 and optical fibers 92. However, another member needed for the optical communication device may be provided. In the optical communication device 900, a beam propagates from the semiconductor laser module 91 through the plurality of optical fibers 92 to the PIC 94. Conventionally, the sum of the intensities of beams propagating from one semiconductor laser module to a PIC is limited by a damage threshold of optical fibers. However, with the configuration of the present embodiment, a beam having an intensity greater than a damage threshold of the optical fiber can propagate to the PIC. Further, by using the semiconductor laser module 91, it becomes possible to mount a semiconductor laser element, a beam branching configuration (beam branching substrate), and an optical fiber into a housing (e.g., QSFP-DD (length 36 mm) or OSFP (length 75.5 mm)) of a semiconductor laser module intended to be used for Co-packaged optics, even in a case of branching a beam in the semiconductor laser module.

In the configuration of the present embodiment, since the semiconductor laser module 91 and the Co-packaged chip 93 are connected via the optical fibers 92, the physical distance between the semiconductor laser module 91 and the Co-packaged chip 93 can be made long. Thus, the physical distance between the semiconductor laser module 91 and the ASIC 95 can be made long, so that an effect of suppressing deterioration in characteristics of the semiconductor laser due to temperature increase in the ASIC 95 in the Co-packaged chip 93, which is one of objects in conventional Co-packaged optics, is also ensured.

Although various exemplary embodiments and examples are described in the present application, various features, aspects, and functions described in one or more embodiments are not inherent in a particular embodiment, and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included.

### DESCRIPTION OF THE REFERENCE CHARACTERS

1, 1a, 1b, lc semiconductor laser element
2, 2a beam branching substrate
3, 3a, 3b, 3a1, 3a2, 3b1, 3b2, 92 optical fiber
4 condenser lens
41 diffraction grating structure
20a dielectric substrate
20b first dielectric layer
21, 211, 212 input waveguide
22, 22a, 22b, 22c, 22d, 221, 222 branching portion
23, 23a, 23b, 23a1, 23a2, 23b1, 23b2 output waveguide
25 groove
31 spot size converter
32 window structure
100, 600, 700, 800, 91 semiconductor laser module
900 optical communication device

1. A semiconductor laser module comprising:
a semiconductor laser element;
a beam branching substrate formed by a dielectric and having an input waveguide with which a laser beam outputted from the semiconductor laser element is coupled, and a branching portion at which the input waveguide branches into a plurality of output waveguides, so that laser beams are respectively outputted from the plurality of output waveguides; and
a plurality of optical fibers with which the plurality of laser beams outputted from the plurality of output waveguides are respectively coupled
wherein a beam damage threshold of each of the plurality of optical fibers is lower than a maximum beam intensity of the laser beam outputted from the semiconductor laser element.

2. (canceled)

3. The semiconductor laser module according to claim 1, wherein
the beam branching substrate includes a dielectric substrate and a first dielectric layer formed on a surface of the dielectric substrate, and
each of the input waveguide, the branching portion, and the output waveguides is formed inside the first dielectric layer by a second dielectric material having a higher refractive index than a refractive index of the first dielectric layer.

4. The semiconductor laser module according to claim 3, wherein
a material of the first dielectric layer is SiO₂, and the second dielectric material is Si or SiN.

5. The semiconductor laser module according to claim 1, wherein
the laser beam is coupled with the input waveguide via a window structure.

6. The semiconductor laser module according to claim 1, wherein
a spot size converter is provided at a part where the laser beam is coupled in the input waveguide.

7. The semiconductor laser module according to claim 1, wherein
a diffraction grating structure is provided on an input side of the input waveguide, and
the laser beam outputted from the semiconductor laser element is coupled with the diffraction grating structure and thus propagates to the input waveguide.

8. The semiconductor laser module according to claim 1, wherein
the laser beam outputted from the semiconductor laser element has evanescent light, and the evanescent light is coupled with the input waveguide.

9. The semiconductor laser module according to claim 1, wherein
the laser beam outputted from the semiconductor laser element is coupled with the input waveguide via a lens.

10. The semiconductor laser module according to claim 1, wherein
grooves are provided at positions where the laser beams are respectively outputted from the plurality of output waveguides, in the beam branching substrate, and
the plurality of optical fibers are respectively placed at the grooves.

11. An optical communication device comprising the semiconductor laser module according to claim 1,

12. An optical communication device comprising a semiconductor laser module which includes
a semiconductor laser element;
a beam branching substrate formed by a dielectric and having an input waveguide with which a laser beam outputted from the semiconductor laser element is coupled, and a branching portion at which the input waveguide branches into a plurality of output waveguides, so that laser beams are respectively outputted from the plurality of output waveguides; and
a plurality of optical fibers with which the plurality of laser beams outputted from the plurality of output waveguides are respectively coupled.
